(19) United States
(12) Patent Application Publication
(10) Pub. No.: US 2025/0333879 A1
(43) Pub. Date: Oct. 30, 2025

(54) METHOD FOR IMPROVING INTENSE LASER-INDUCED DAMAGE RESISTANCE OF NONLINEAR SYNTHETIC CRYSTALS

(71) Applicant: RESEARCH CENTER OF LASER FUSION, CHINA ACADEMY OF ENGINEERING PHYSICS, Mianyang (CN)

(72) Inventors: Wei HONG, Mianyang (CN); Liening WEI, Mianyang (CN); Fei YANG, Mianyang (CN); Guixia YANG, Mianyang (CN); Fang TAN, Mianyang (CN); Jian TENG, Mianyang (CN); Xuqiang LIU, Mianyang (CN); Lei YU, Mianyang (CN); Xinda ZHOU, Mianyang (CN); Xiangxu CHAI, Mianyang (CN)

(73) Assignee: RESEARCH CENTER OF LASER FUSION, CHINA ACADEMY OF ENGINEERING PHYSICS, Mianyang (CN)

(21) Appl. No.: 18/814,580

(22) Filed: Aug. 25, 2024

(30) Foreign Application Priority Data
Apr. 26, 2024 (CN) 202410517076.5

(51) Int. Cl. C30B 33/02; G02F 1/355

(52) U.S. Cl. CPC C30B 33/02; G02F 1/3553

(57) ABSTRACT

The invention belongs to the technical field of nonlinear synthetic crystals, and particularly relates to a method for improving the intense laser-induced damage resistance of nonlinear synthetic crystals. The method comprises: electrifying nonlinear synthetic crystals by means of a stabilized DC power supply under a certain atmosphere. The invention can effectively decrease the density of pinpoint damage in nonlinear synthetic crystals by means of an “electrification method”, thus optimizing the intense laser-induced damage resistance of the nonlinear synthetic crystals and particularly fulfilling a more obvious improvement effect on defects with a greater damage threshold. The electrification method provided by the invention is expected to further reduce the damage probability in a case where an ultraviolet nanosecond pulse laser fluence with a wavelength of 355 nm or 351 nm is greater than 8J/cm² to improve the damage resistance of crystals. The electrification method further implemented based on laser conditioning provided by the invention is a novel comprehensive method for improving the damage resistance of crystals and has a great has a great economical advantage.

### CROSS-REFERENCE TO RELATED APPLICATIONS

This application claims priority of Chinese Patent Application No. 202410517076.5, filed on Apr. 26, 2024, the entire contents of which are incorporated herein by reference.

### TECHNICAL FIELD

The invention belongs to the technical field of nonlinear synthetic crystals, and particularly relates to a method for improving the intense laser-induced damage resistance of nonlinear synthetic crystals.

### BACKGROUND

Nonlinear synthetic crystals are essential key optical materials in laser devices and large laser facilities. Potassium dihydrogen phosphate (KDP) nonlinear crystals and other homogeneous crystals with similar lattice structures such as potassium dideuterium phosphate (DKDP) crystals with different deuteration ratios and ammonium dihydrogen phosphate (ADP) crystals are important nonlinear synthetic crystals which have a wide commercial application at present. These crystals are often used as frequency multiplication elements or electro-optical switch elements in laser facilities and always exposed to intense laser irradiation. When the intensity I (unit: W/cm²) of laser irradiated onto the crystals is greater than a threshold (Ith), irreversible laser-induced damage will be formed in the crystals, and the main damage is pinpoint bulk damage which is distributed discretely in space. An important physical quantity for describing the pinpoint bulk damage is the damage probability (P) measured with small-aperture laser (the beam area is about 1 mm2) based on an 1on1 method, which uses pulse laser with the same intensity to irradiate different positions of a crystal to detect the probability of pinpoint bulk damage of the crystal. The damage probability is positively related to the quantity of intense laser-induced pinpoint bulk damage in a crystal in unit volume (φ. To ensure that a laser device can operate normally, ρ should be as small as possible. With the increase of ρ, the dissipation of laser energy will be more intense, the influence of scattered laser on elements of the laser device will be greater, and a transmitted beam will be modulated more obviously. Therefore, the study of the reduction of the probability of pinpoint damage under a certain laser intensity is of great significance for improving the performance of crystals.

To improve the ability to resist intense laser-induced damage of grown KDP and homogeneous crystals, two techniques, which are a thermal annealing technique and a laser conditioning technique, are developed in the past forty years. According to the thermal annealing technique, the temperature of crystals is slowly increased to be over 100° C., held for a certain time and then slowly decreased to the room temperature. According to the laser conditioning technique, assume the damage threshold of non-processed KDP and homogeneous crystals is Ith_i, if the crystals are irradiated with laser the laser intensity of which is greater than Ith_i, irreversible bulk damage will be caused in the crystals; however, if the crystals are irradiated with laser the laser intensity of which is slightly less than Ith_i, for example, with pulse laser the light intensity of which is half of Ith_i, and then with laser the laser intensity of which is Ith_i, the crystals will not be damaged, thus increasing the damage threshold of the crystals.

Although these two crystal processing techniques can reduce defects in crystals to improve to some extent the intense laser-induced damage resistance of the crystals, there is a bottleneck in performance improvement. After the two methods are comprehensively optimized, the intense laser-induced damage resistance of KDP crystals can only reach a certain level, and a novel method is needed to further improve the intense laser-induced damage resistance of the KDP crystals. In addition, the economic cost of the laser conditioning technique is high, so a more economical method is needed.

### SUMMARY

The objective of the invention is to provide a method for improving the intense laser-induced damage resistance of nonlinear synthetic crystals, which can effectively decrease the density of pinpoint damage in nonlinear synthetic crystals by means of an “electrification method” to reduce the damage probability of the crystals, thus optimizing the intense laser-induced damage resistance of the nonlinear synthetic crystals and particularly fulfilling a more obvious improvement effect on defects with a greater damage threshold.

To fulfill the above objective, the invention provides the following technical solution:
the invention provides a method for improving the intense laser-induced damage resistance of nonlinear synthetic crystals, comprising the following step:
electrifying nonlinear synthetic crystals by means of a stabilized DC power supply.

Preferably, the nonlinear synthetic crystals are electrified at a voltage of 0.5-100 kV.

Preferably, the nonlinear synthetic crystals are electrified for 3-48 hrs.

Preferably, when electrified, the nonlinear synthetic crystals have a temperature of 20-25° C.

Preferably, the nonlinear synthetic crystals comprise DKDP nonlinear optical crystals or nonlinear optical crystals with a similar crystal structure to the DKDP nonlinear optical crystals.

Preferably, the nonlinear synthetic crystals comprise KDP, DKDP or ADP crystals.

Preferably, the nonlinear synthetic crystals are electrified under a normal pressure or vacuum condition.

Preferably, the nonlinear synthetic crystals are nonlinear synthetic crystals subjected to thermal annealing.

The invention provides a method for improving the intense laser-induced damage resistance of nonlinear synthetic crystals, comprising the following step: electrifying nonlinear synthetic crystals by means of a stabilized DC power supply. Bulk damage will be formed in nonlinear synthetic crystals under the action of intense laser. The morphology of the mostly common bulk damage is hollow tiny explosion pits with a size from several microns to dozens of microns, and such damage is generally referred to as pinpoint damage. In a case where the laser intensity exceeds the damage threshold of crystals, the density (pp) of pinpoint damage in the crystals will change within 10-2-106/mm3 due to the difference in density of damaged precursors in the crystals. With the increase of the density of pinpoint damage, damage to laser devices using the crystals will be greater. A deep study on the damage mechanism of crystals is necessary for the development of techniques for improving the laser-induced damage resistance of nonlinear synthetic crystals. There has been some, but not completed, understanding of the physical mechanism of the generation of pinpoint bulk damage of KDP crystals under the action of intense laser. It is generally recognized that the cause of pinpoint damage of the KDP crystals under the action of intense laser is the pre-existence of damaged precursors with a size of hundreds of nanometers, such as about 100 nm, in the crystals, and the precursors have point defects, the concentration of which is about 1019/cm3. For a specific precursor, the damage threshold will decrease will the increase of the concentration of defects in the precursor. In the study of the damage mechanism of the KDP crystals, the specific type of point defects in the precursors with a size of hundreds of nanometers still remains a trouble to people. In the invention, point defects of DKDP crystals and homogeneous crystals are studied by means of the electron paramagnetic resonance technique to obtain a new deep understanding of the physical mechanism of intense laser-induced damage of crystals. Most importantly, it is inferred, based on electron paramagnetic resonance test results, that specific point defects are interstitial hydrogen (deuterium) and hydrogen (deuterium) vacancies. Based on such an understanding, the invention provides and experimentally verifies a novel method for improving the damage resistance of crystals by reducing the concentration of point defects in precursors with a size of hundreds of nanometers. The invention proposes a novel crystal processing method (electrification method). Because the interstitial hydrogen (deuterium) and hydrogen (deuterium) vacancies in the precursors with a size of hundreds of nanometers are electrical point defects, if a steady electric field above a certain intensity is applied to the point defects, positive electrical interstitial hydrogen (deuterium) will migrate in damaged precursors in the direction of the electric field and negative electrical hydrogen (deuterium) will migrate in the damaged precursors in a direction opposite to the direction of the electric field, under the action of a powerful electric field force. When the migration distance of the electrical hydrogen (deuterium) significantly exceeds the size of the precursors, the concentration of point defects in the precursors will decrease to increase the damage threshold of the damaged precursors, thus effectively decreasing the density of pinpoint damage formed under a certain laser intensity. The method for improving the intense laser-induced damage resistance of crystals by electrifying the crystals in the invention is completely different from the traditional annealing and laser processing methods. The method provided by the invention can greatly reduce the probability of pinpoint damage, thus optimizing the intense laser-induced damage resistance of nonlinear synthetic crystals and particularly fulfilling a more obvious improvement effect on defects with a greater damage threshold.

### BRIEF DESCRIPTION OF THE DRAWINGS

FIG. 1 is a schematic diagram of the position and size of crystals used for a DKDP crystal electrification test according to one embodiment of the invention;

FIG. 2 is a schematic structural diagram of an electrification tank used for DKDP crystal electrification according to one embodiment of the invention;

In FIG. 2:1, tank body; 2, ceramic plate; 3, clamp; 4, nonlinear synthetic crystal; 5, first metal electrode; 6, second metal electrode; 7, second terminal; 8, first terminal; 9, temperature sensor;

FIG. 3 is an image of the electrification tank used for DKDP crystal electrification according to one embodiment of the invention;

FIG. 4 illustrates a light path for measuring damage probability curves of DKDP crystals with small-aperture triple-frequency laser;

FIG. 5 illustrates comparative test results of damage probability curves of DKDP crystals which are not electrified and electrified in Embodiment 1.

### DETAILED DESCRIPTION

The invention provides a method for improving the intense laser-induced damage resistance of nonlinear synthetic crystals, comprising the following step:

nonlinear synthetic crystals are electrified by means of a constant DC power supply.

In the invention, unless otherwise specifically stated, all raw materials/components are commercially available products familiar to those skilled in the art.

In the invention, the nonlinear synthetic crystals preferably comprise DKDP nonlinear optical crystals or nonlinear optical crystals with a similar crystal structure to the DKDP nonlinear optical crystals, and more preferably comprise KDP, DKDP or ADP crystals. In the invention, the deuteration ratio of the DKDP nonlinear optical crystals is preferably 5-98%. In a specific embodiment of the invention, the “electrification method” provided by the invention will be described in detail with DKDP crystals as an example. The deuteration ratio of the DKDP crystals is 70%. The DKDP crystals are insulators and have a large energy gap (Eg). The energy gap of the DKDP crystals is 7.5-9 e V.

In the invention, the nonlinear synthetic crystals are preferably nonlinear synthetic crystals subjected to thermal annealing. In a specific embodiment of the invention, the size of the nonlinear synthetic crystals is 1 cm×1 cm×5 cm. In the invention, before electrification, a nonlinear synthetic crystal boule which is artificially grown and subjected to thermal annealing is preferably cut according to a specific direction and size in terms of crystal application requirements. In a specific embodiment of the invention, type-II matching cutting is performed on the nonlinear synthetic crystal boule which is artificially grown and subjected to thermal annealing to obtain a crystal with a size of 5 cm×5 cm×1 cm, and then the crystal is further cut.

In the invention, surfaces of the nonlinear synthetic crystals preferably have an optical-level finish degree. In the invention, before electrification, the nonlinear synthetic crystals are preferably polished. In a specific embodiment of the invention, the nonlinear synthetic crystals are polished preferably by fly cutting.

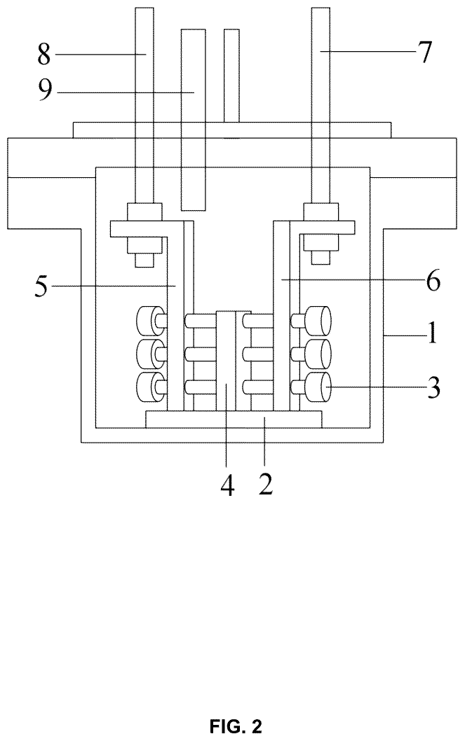

In the invention, the nonlinear synthetic crystals are electrified preferably in a crystal electrification tank. The schematic structural diagram of the crystal electrification tank used in one embodiment of the invention is shown in FIG. 2. The crystal electrification tank comprises a tank body, a ceramic plate arranged on a bottom surface of the inside of the tank body, crystal clamps and parallel metal plate electrodes arranged in the tank body, and a sealing cover, wherein the sealing cover is provided with a temperature sensor and metal electrode fixing parts. The tank body of the crystal electrification tank is made of stainless steel. In the invention, the nonlinear synthetic crystals are preferably clamped between the pair of electrified metal plate electrodes parallel to each other and then placed in the stainless steel electrification tank. In the invention, before electrification, air in the crystal electrification tank is pumped out by means of a vacuum pump until the degree of vacuum in the tank body reaches 10-3 Pa, then dry nitrogen is injected into the tank body, and after that, the crystal electrification tank is placed in an incubator; and during electrification, the temperature control accuracy of the incubator is 0.1° C. In the invention, dry nitrogen is injected into the tank body to ensure that an insulation atmosphere in the tank body to apply a sufficient electric field intensity to the crystals. In the invention, the power supply is a stabilized DC power supply. The invention adopts a high-voltage DC power supply to continuously provide a stable DC voltage for the crystals. In the invention, the nonlinear synthetic crystals are electrified preferably at a voltage of 0.5-100 kV, more preferably 0.8 kV, 0.95 kV or 10 kV. The nonlinear synthetic crystals are electrified preferably for 3-48 hrs, preferably 3 hrs, 8 hrs or 48 hrs. In a specific embodiment of the invention, the voltage and time for electrifying the nonlinear synthetic crystals are related to defect parameters of the nonlinear synthetic crystals. With the increase of the voltage for electrifying the nonlinear synthetic crystals, the time for electrifying the nonlinear synthetic crystals will be shorter. However, at a specific voltage, a saturation effect will occur with time, that is, the damage resistance will not be improved anymore. In a specific embodiment of the invention, in a case where the thickness of the nonlinear synthetic crystals is preferably 1 cm, the nonlinear synthetic crystals are electrified preferably at a voltage of 0.5×10³V-10⁵V. In the invention, when electrified, the nonlinear synthetic crystals have a temperature of 20-25° C. A protective gas is preferably nitrogen, and the pressure of the protective gas is preferably the normal pressure.

In the invention, the cause of pinpoint bulk damage in nonlinear synthetic crystals including KDP (DKDP) crystals under the action of intense laser is the presence of discretely distributed defects in the artificially grown crystals, and generally, these defects are also referred to as damaged precursors, the size of which is about 100 nm and in which there are hydrogen-related point defects with a concentration of about 1019/cm³, and specifically, the point defects are interstitial hydrogen (deuterium) and hydrogen (deuterium) vacancies, which are all electrical point defects. If a steady electric field with a certain intensity is applied to the point defects, positive electrical interstitial hydrogen (deuterium) will migrate in the damaged precursors in the direction of the electric field and negative electrical hydrogen (deuterium) will migrate in the damaged precursors in a direction opposite to the direction of the electric field, under the action of a powerful electric field force. When the migration distance of the electrical hydrogen (deuterium) significantly exceeds the size of the precursors, the concentration of point defects in the precursors will decrease to increase the damage threshold of the damaged precursors, thus effectively decreasing the density of pinpoint damage formed under a certain laser intensity.

Because the hydrogen (deuterium) and hydrogen (deuterium) vacancies have opposite electrical polarities, the hydrogen (deuterium) and hydrogen (deuterium) vacancies will be mutually attracted, and the driving electric field should reach a certain intensity to separate the hydrogen (deuterium) from hydrogen (deuterium) vacancies. With the decrease of the concentration of hydrogen-related point defects in the precursors, the damage threshold will be increased correspondingly, and the electric field intensity for migrating point defects out of the precursors will be lower, and this also explains why electrification has a more remarkable processing effect on defects with a high damage threshold.

The invention adopts the electrification method as a novel method for processing KDP and homogeneous crystals, greatly reduces the damage probability of the crystals, and is expected to fulfill a better experiment effect.

The laser conditioning technique that is most widely used for KDP/DKDP crystals at present processes KDP/DKDP crystals by means of triple-frequency laser (with a wavelength of 355 nm) output by a sub-nanosecond Nd:YAG laser device. The latest preprocessing experimental results are published in Acta Physica Sinica in 2021 (Off-line sub-nanosecond laser conditioning on large aperture deuterated potassium dihydrogen phosphate crystal Liu Zhi-Chao et al., Acta Physica Sinica, 2021), and the experimental parameters as described by the author are: the pulse width of pulse laser applied to DKDP crystals to be preprocessed is about 0.5 nanosecond, the spot diameter is 0.68 mm, the wavelength is 355 nm, the maximum laser fluence for preprocessing is 2 J/cm², and the maximum laser power density is 4 GW/cm². By sub-nanosecond laser conditioning, the zero-probability bulk damage threshold of DKDP crystals can be increased by about 1 time (Study of the Effect of Annealing on Damage of DKDP Crystals in Abstracts of Academic Paper of the 4^{th} National Congress of Members (Academic Conference) of China Union of Crystallography, Sun Shao-Tao, Wang Zheng-Ping and Xu Xin-Guang, 2008) (see FIG. 11 in Literature 2), and reaches about 8 J/cm².

The electrification method provided by the invention is expected to further reduce the damage probability in a case where the laser fluence is greater than 8 J/cm² to improve the damage resistance of crystals. Therefore, the electrification method further implemented based on laser conditioning provided by the invention is a novel method for improving the damage resistance of crystals.

In addition, the price of laser conditioning equipment at present is about three million yuan, while the price of the processing device used for the electrification method provided by the invention is about 100,000 yuan, so the method provided by the invention has a great economical advantage.

To further explain the invention, the technical solution provided by the invention is described in detail below in conjunction with embodiments, but these embodiments should not be construed as limitations of the protection scope of the invention.

### Embodiment 1

In this embodiment, DKDP crystals were used by way of examples, the DKDP crystals had an energy gap of (7.5-9) eV, were unlikely to conduct electricity by means of electrons and holes because of their low electron concentration and hole concentration at room temperature, and were insulators with a low DC conductivity. In addition, the DKDP crystals contained hydrogen bonds with bond energy less than 1 eV and could generate negative univalent hydrogen vacancies and positive univalent interstitial hydrogen at room or higher temperature, and these two types of defects formed conductive carriers under the action of an external electric field, so the DKDP crystals were ionically conductive.

This embodiment provides a method for improving the laser-induced damage resistance of DKDP crystals, specifically comprising the following steps:

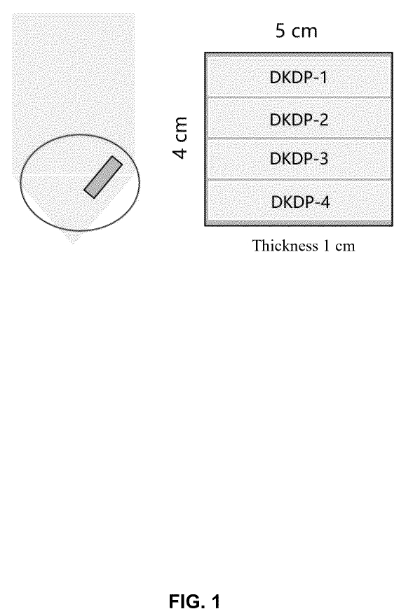

Step 1: a DKDP crystal boule which was artificially grown and subjected to thermal annealing was obtained and, as shown in FIG. 1, was cut according to a specific direction and size in terms of crystal application requirements, (in this embodiment, type-II matching cutting was performed on the crystal boule) to obtain a crystal with a size of 5 cm×5 cm×1 cm.

Step 2: the crystal was further cut to obtain four cuboid crystals, the initial positions of which were adjacent and the size of which was 5 cm×1 cm×1 cm, wherein the four cuboid crystals had basically the same initial laser-induced damage resistance. The surfaces of the crystals obtained by cutting were polished by a process (such as fly cutting) until the surfaces of the crystals reached an optical-level finish degree.

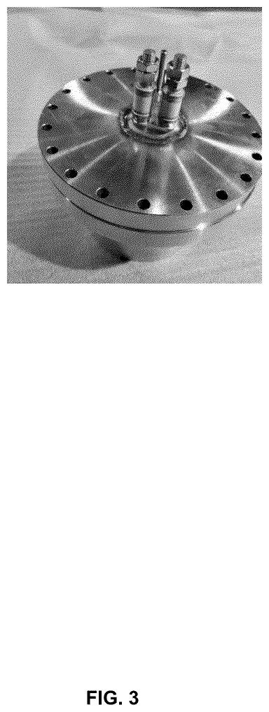

Step 3: in this embodiment, the crystals were electrified in a crystal electrification tank shown in FIG. 2 and FIG. 3. The DKDP crystals with a size of 1 cm×1 cm×5 cm obtained in Step 2 were stably clamped in a pair of metal electrodes which were electrified and then placed in the stainless steel electrification tank. Before electrification, first, air in the electrification tank was pump out by means of a vacuum pump until the degree of vacuum in the tank body reached 10.3 Pa; then, dry nitrogen at an atmospheric pressure was injected into the tank body; and after that, the electrification tank was placed in an incubator, and during electrification, the temperature control accuracy of the incubator was 0.1° C., and the temperature of the crystals was 25° C. A high-voltage DC power supply provided a stable DC voltage for the crystals. The crystal DKDP-1 was electrified at a voltage of 0.95 kV for 48 hrs, the crystal DKDP-2 was electrified at a voltage of 10 kV for 3 hrs, the crystal DKDP-3, as a contrast sample, was not electrified, and the crystal DKDP-4 was electrified at a voltage of 0.8 kV for 8 hrs.

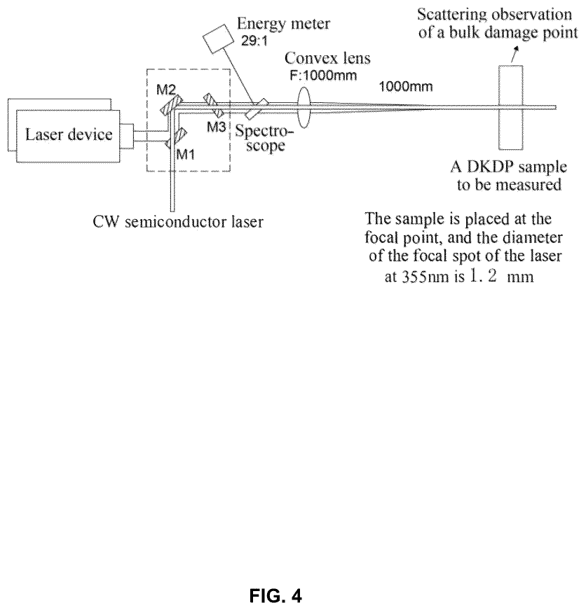

Step 4: laser damage probability curves of the electrified DKDP crystals were measured with a small-aperture laser device (the beam area was about 1 mm2) with a wavelength of 355 nm to evaluate the intense laser-induced damage resistance of the DKDP crystals, wherein the laser pulse width was 5 ns, and the near-field modulation degree of the beam was 2.4. An 1on1 method was used for measurement, and the DKDP crystals were measured ten times under each laser fluence. The light path of the laser device is shown in FIG. 4.

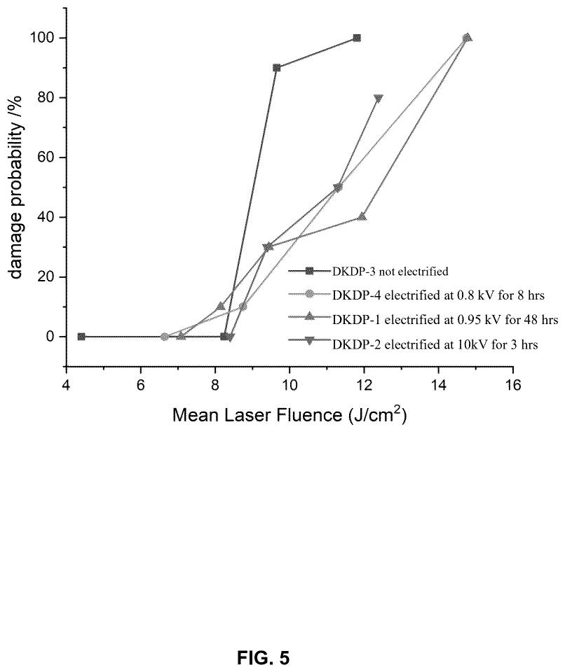

Test results of the damage probability curves of the four crystals in Embodiment 1 obtained by electrification are shown in FIG. 5. The horizontal axis in FIG. 5 indicates the mean laser fluence of test laser with a pulse width of 5 ns and a wavelength of 355 nm, and the vertical axis in FIG. 5 indicates the damage probability of the DKDP crystals under certain laser fluence. Generally, it can be seen that under the same laser intensity, the damage probability of the electrified crystals was greatly reduced as compared with the crystal that was not electrified, indicating that the damage probability of the DKDP crystals can be obviously reduced by applying a steady direct-current electric field with a certain intensity to the DKDP crystals for a certain time. Experimental data of the four crystals in Embodiment 1 are summarized in Table 1. It can be seen from Table 1 that according to data in Group 1, when the laser fluence was about 9.6 J/cm², the damage probability of the crystal DKDP-3 that was not electrified was 90%, and the damage probability of the other three electrified crystals was 20%-30%. According to data in Group 2, when the laser fluence was about 9.6 J/cm², the damage probability of the crystal DKDP-3 that was not electrified was 100%, and the damage probability of the other three electrified crystals was 40%-50%. The two groups of data indicate that the damage probability of electrified crystals is reduced by over 50%.

TABLE 1
Experimental data of changes in the damage probability
of DKDP crystals before and after electrification

| | | Group 1 | | Group 2 | |
|---|---|---|---|---|---|
| | | Laser | Damage | Laser | Damage |
| Crystal | Electrification | fluence | probability | fluence | probability |
| number | parameter | (J/cm²) | (%) | (J/cm²) | (%) |
| DKDP-3 | Not electrified | 9.7 | 90 | 11.8 | 100 |
| DKDP-1 | Electrified at 0.95 | 9.4 | 30 | 11.9 | 40 |
| | kV for 48 hrs | | | | |
| DKDP-2 | Electrified at 10 | 9.4 | 30 | 11.3 | 50 |
| | kV for 3 hrs | | | | |
| DKDP-4 | Electrified at 0.8 | 9.6 | 20 | 11.3 | 50 |
| | kV for 8 hrs | | | | |

The above results indicate that by electrifying the DKDP crystals, the damage probability of the DKDP crystals can be reduced, the intense laser-induced damage resistance of the DKDP crystals can be optimized, and particularly, a more obvious improvement effect can be fulfilled for defects with a greater damage threshold.

According to the above embodiment, the method for improving the intense laser-induced damage resistance of nonlinear synthetic crystals provided by the invention comprises the following step: nonlinear synthetic crystals are electrified in a protective gas atmosphere by means of a power supply. The invention can effectively decrease the density of pinpoint damage in nonlinear synthetic crystals by means of the “electrification method” to reduce the damage probability of the crystals, thus optimizing the intense laser-induced damage resistance of the nonlinear synthetic crystals and particularly fulfilling a more obvious improvement effect on defects with a greater damage threshold. The electrification method provided by the invention is expected to further reduce the damage probability in a case where the laser fluence is greater than 8 J/cm² to improve the damage resistance of crystals. Therefore, the electrification method further implemented based on laser conditioning provided by the invention is a novel comprehensive method for improving the damage resistance of crystals and has a great has a great economical advantage.

Although the invention is described in detail with reference to the above embodiments, the above embodiments are merely illustrative ones and are not all possible ones of the invention, other embodiments can be obtained according to the above embodiments without creative labor, and all these embodiments should fall within the protection scope of the invention.

What is claimed is:

1. 1. A method for improving the intense laser-induced damage resistance of nonlinear synthetic crystals, comprising the following step:
electrifying nonlinear synthetic crystals by means of a stabilized DC power supply.

2. The method for improving the intense laser-induced damage resistance of nonlinear synthetic crystals according to claim 1, wherein the nonlinear synthetic crystals are electrified at a voltage of 0.5-100 kV.

3. The method for improving the intense laser-induced damage resistance of nonlinear synthetic crystals according to claim 1, wherein the nonlinear synthetic crystals are electrified for 3-48 hrs.

4. The method for improving the intense laser-induced damage resistance of nonlinear synthetic crystals according to claim 1, wherein when electrified, the nonlinear synthetic crystals have a temperature of 20-25° C.

5. The method for improving the intense laser-induced damage resistance of nonlinear synthetic crystals according to claim 1, wherein the nonlinear synthetic crystals comprise DKDP nonlinear optical crystals or nonlinear optical crystals with a similar crystal structure to the DKDP nonlinear optical crystals.

6. The method for improving the intense laser-induced damage resistance of nonlinear synthetic crystals according to claim 1, wherein the nonlinear synthetic crystals comprise KDP, DKDP or ADP crystals.

7. The method for improving the intense laser-induced damage resistance of nonlinear synthetic crystals according to claim 1, wherein the nonlinear synthetic crystals are electrified under a normal pressure or vacuum condition.

8. The method for improving the intense laser-induced damage resistance of nonlinear synthetic crystals according to claim 1, wherein the nonlinear synthetic crystals are nonlinear synthetic crystals subjected to thermal annealing.
